(19) United States
(12) Patent Application Publication
(10) Pub. No.: US 2025/0347782 A1
(43) Pub. Date: Nov. 13, 2025

(54) OPTICAL SENSOR

(71) Applicant: DENSO CORPORATION, Kariya-city (JP)

(72) Inventors: Seiya TAKATA, Kariya-city (JP); Kenji INAZU, Kariya-city (JP); Akifumi UENO, Kariya-city (JP)

(21) Appl. No.: 19/287,679

(22) Filed: Jul. 31, 2025

Related U.S. Application Data
(63) Continuation of application No. PCT/JP2024/001182, filed on Jan. 18, 2024.

(30) Foreign Application Priority Data
Feb. 6, 2023 (JP) 2023-016177

(51) Int. Cl. G01S 7/484; G01S 7/497

(52) U.S. Cl. CPC G01S 7/484; G01S 7/497

(57) ABSTRACT

An optical sensor comprises a light projector unit that generates a projected light beam by a light source element, a light receiver unit that outputs a detection signal by receiving a reflected beam, and a control unit that controls the light projector unit and the light receiver unit. A control unit is configured to perform: monitoring a heat transfer temperature Tt transferred to a surroundings of a light source element in a light projector unit; and controlling a luminous output PI at the light source element so as to absorb a temperature change amount in a junction temperature Tj at the light source element, which is correlated with an efficiency change amount of a luminous efficiency that decreases as the heat transfer temperature Tt increases at the light source element and a heat transfer change amount in the heat transfer temperature Tt.

### CROSS REFERENCE TO RELATED APPLICATIONS

The present application is a continuation application of International Patent Application No. PCT/JP2024/001182 filed on Jan. 18, 2024, which designated the U.S. and is based on and claims the benefit of priority from Japanese Patent Application No. 2023-16177 filed on Feb. 6, 2023, the entire disclosure of the above application is incorporated herein by reference.

### TECHNICAL FIELD

The present disclosure relates to an optical sensor.

### BACKGROUND

An optical sensor may include components such as a light source element to generate a light beam to scan a target area. During a use of the optical sensor, components are degraded and affect the lifetime of the optical sensor. In the above aspects, or in other aspects not mentioned, there is a need for further improvements in an optical sensor and components thereof.

### SUMMARY

According to an aspect of the present disclosure,
an optical sensor that emits a projected light beam and receives a reflected light beam reflected in response to the projected light beam, the optical sensor comprises:
a light projector unit that generates a projected light beam by a light source element;
a light receiver unit that outputs a detection signal by receiving the reflected beam; and
a control unit that controls the light projector unit and the light receiver unit, wherein
the control unit is configured to perform:
monitoring a heat transfer temperature transferred to a surroundings of the light source element at the light projector unit; and
controlling a luminous output at the light source element to absorb a temperature change amount in a junction temperature at the light source element, which correlates an efficiency change amount in a luminous efficiency that decreases as the heat transfer temperature increases at the light source element and a heat transfer change amount in the heat transfer temperature.

Thus, in the light projector unit according to an aspect of the present disclosure, a heat transferred temperature transferred to a surroundings of the light source element is monitored by the control unit. Then, in the control unit, it is further focused that a temperature change amount in a junction temperature at the light source element, which correlates to an efficiency change amount in a luminous efficiency, which decreases as the heat transfer temperature increases at the light source element, and a heat transfer change amount in the heat transfer temperature. Then, in the control unit, the luminous output at the light source element is controlled to absorb the temperature change amount in the junction temperature, as a result, it is possible to suppress a decrease in the life of the light source element caused by temperature rise and to ensure durability.

### BRIEF DESCRIPTION OF DRAWINGS

The disclosure is further described with reference to the accompanying drawings in which:

FIG. 1 is a cross-sectional view showing an entire configuration of an optical sensor according to the first embodiment;

FIG. 2 is a schematic diagram showing a projector light source unit according to the first embodiment;

FIG. 3 is a diagram showing a time chart for explaining operations of the projector light source unit according to the first embodiment;

FIG. 4 is a schematic diagram showing the light receiver detection unit according to the first embodiment;

FIG. 5 is a block diagram showing a circuit configuration of the projector light source unit according to the first embodiment;

FIG. 6 is a circuit diagram showing the detailed configuration of a power circuit according to the first embodiment;

FIG. 7 is a circuit diagram showing the detailed configuration of a regulator circuit according to the first embodiment;

FIG. 8 is a circuit diagram showing the detailed configuration of a temperature measurement circuit according to the first embodiment;

FIG. 9 is a graph illustrating a principle of control by a control unit of the first embodiment;

FIG. 10 is a graph illustrating a principle of control by a control unit of a second embodiment;

FIG. 11 is a graph showing a characteristic of the power circuit according to a third embodiment; and

FIG. 12 is a circuit diagram showing the detailed configuration of the regulator circuit according to a variation of FIG. 7.

### DETAILED DESCRIPTION

Optical sensors that emit a projected light beam and receive a reflected light beam reflected in response to the projected light beam are widely known. As a type of such optical sensors, U.S. Pat. No. 677,898 P1 discloses a sensor that outputs a detection signal by receiving a reflected beam at a light receiver unit in response to a projected light beam generated by a light source element in a light projector unit.

In the optical sensor disclosed in U.S. Pat. No. 677,898, P1, an amount of radiation energy from the light source element is increased while the detection signal is lower than a reference signal and is not saturated. As a result, under conditions where an ambient temperature of the light source element is high, the temperature of the light source element will continue to rise in response to an increase in the amount of radiation energy, which may lead to a durability problem in a form of a decrease in a life of the light source element.

It is an object of the present disclosure to provide optical sensors that ensure durability.

Hereinafter, technical means of the present disclosure for solving the issue is described.

The following describes embodiments of the present disclosure with reference to the drawings. It should be noted that the same reference numerals are assigned to corresponding components in the respective embodiments, and overlapping descriptions may be omitted. If only a part of the configuration is described in the respective embodiments, the configuration of the other embodiments described before may be applied to other parts of the configuration. Furthermore, in addition to combinations of components explicitly described in each embodiment, it is also possible to combine components from different embodiments, as long as the combination poses no difficulty, even if not explicitly described.

### First Embodiment

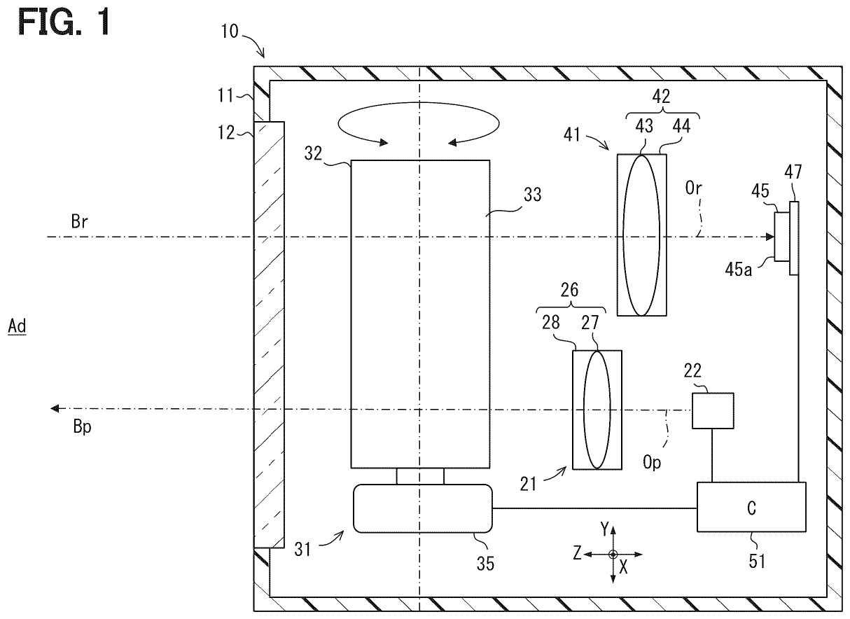

As shown in FIG. 1, an optical sensor 10 according to a first embodiment of the present disclosure is LiDAR (Light Detection and Ranging/Laser Imaging Detection and Ranging) which is placed on a moving object to optically observing an external environment. The moving object to which the optical sensor 10 is to be placed is a vehicle, such as a car, which is capable of at least one of the following types of operation: manual operation, automated driving, and remote operation. In the following description, unless otherwise specified, each direction indicated by a front, a rear, a top, a bottom, a left, and a right is defined with respect to the vehicle on a horizontal plane. In the following description, a horizontal direction and a vertical direction mean, respectively, parallel and perpendicular directions to the horizontal plane in the vehicle on the horizontal plane.

The optical sensor 10 is disposed in at least one of a front portion, left and right side portions, a rear portion, and an upper roof of the vehicle. The optical sensor 10 projects a projected beam Bp toward a detection area Ad corresponding to a location in the vehicle among the external environments. The optical sensor 10 detects a return light that is returned by reflecting the projected beam Bp by an object in the detection area Ad in the external environment, as a reflected beam Br. Light in the near-infrared region, which is difficult for people to see, is normally selected as the projected beam Bp, which becomes the reflected beam Br.

The optical sensor 10 detects an object in the detection area Ad out of the external environment by receiving the reflected beam Br that is reflected against the projected beam Bp. Such detection of external objects is, for example, one or more types of detection including at least distance from the optical sensor 10 to the object, a direction in which the object is located, and intensity of the reflected beam Br from the object. A typical observation target to be observed by the optical sensor 10 applied to the vehicle may be at least one type of moving object such as a pedestrian, a cyclist, an animal other than a human, or another vehicle. The typical target to be observed by the optical sensor 10 applied to the vehicle is at least one type of stationary object such as a guardrail, a road sign, a structure on a roadside, or a fallen object on a road.

The optical sensor 10 has a three-dimensional coordinate system defined by an X, Y, and Z axes, which are three mutually orthogonal axes. In particular, in the three-dimensional coordinate system of the optical sensor 10, a Y-axis direction is defined along the vertical direction of the vehicle, and X-axis and Z-axis directions are defined along different horizontal directions of the vehicle, respectively. In addition, in FIG. 1, a left side part with respect to a dash-dot-dash line along the Y-axis (a part close to a cover panel 12, which is described later) is a cross section actually perpendicular to a right side part with respect to the dashed-dotted line (a part close to units 21 and 41, which is described later).

The optical sensor 10 includes a housing unit 11, a light projector unit 21, a scanner unit 31, a light receiver unit 41, and the control unit 51. The housing unit 11 having a light shielding characteristic is formed in a box shape from, e.g., metal or resin.

The housing unit 11 houses the light projector unit 21, the scanner unit 31, the light receiver unit 41, and the control unit 51. An opening penetrating through an interior and an exterior in the housing unit 11 is closed by a cover panel 12. The cover panel 12 having a translucent characteristic is formed of resin or glass, for example, and partitions the interior and the exterior of the housing unit 11.

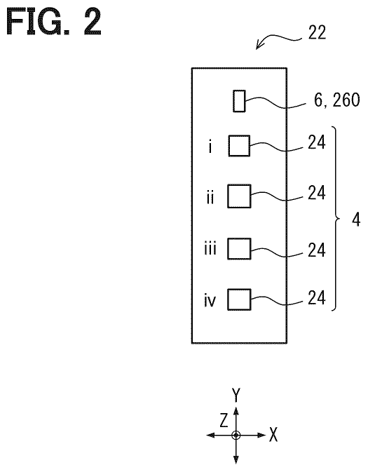

The light projector unit 21 has a projector light source unit 22 and a projector lens unit 26. As shown in FIG. 2, the projector light source unit 22 is constructed by a plurality of light source elements 24 mounted on a substrate in an arrayed manner. In particular, the light source elements 24 of the present embodiment are laser diodes, arranged in a single row, spaced apart from each other along the Y-axis direction. Each one of the light source elements 24 may be an edge-emitter laser or a vertical cavity surface emitting laser (VCSEL).

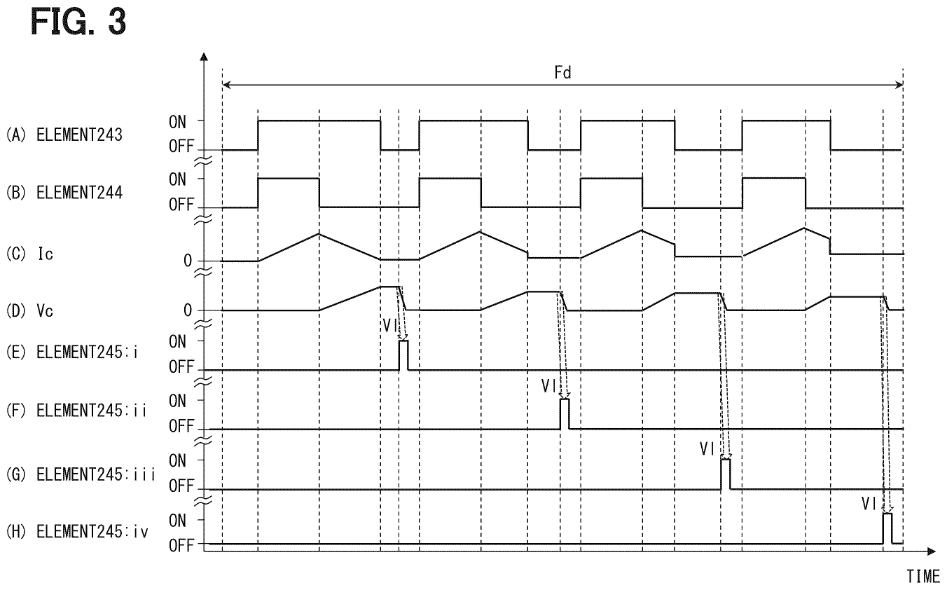

Each one of the light source elements 24 emits light in response to the applied voltage VI, which is applied according to the control signal from the control unit 51, as shown in FIG. 3. As a result, the light source elements 24 generate laser beams, which are the projected light beams Bp, at a pulse luminescence time duration common for them. Particularly here, in the detection frame Fd for each scanning lines shown in FIG. 3, each one of the light source elements 24 emits light sequentially according to the sequence i to iv (see FIG. 2) of the arrangement in the Y-axis direction.

As shown in FIG. 1, the projector lens unit 26 is constructed with at least one projector lens 27 held in a lens barrel 28. At least one projector lens 27 is mainly made of a light-transmitting base material such as resin or glass, and is formed into a lens shape according to an optical function to be demonstrated. The projector lens 27 demonstrates at least one type of optical function, such as focusing, collimating, and shaping, on the projector light beam Bp from the projector light source unit 22. The projector lens 27 is positioned in the lens barrel 261 with a light-shielding property, formed, for example, of metal or resin. The projector lens unit 26 in such a configuration is aligned with the projector light source unit 22 to form a projector optical axis Op that guides the projected light beam Bp toward the scanner unit 31.

The scanner unit 31 has a scanning mirror 32 and a scanning motor 35. The scanning mirror 32 is formed into a plate shape by vapor deposition of a reflective film on a reflective surface 33, which is one side of a base material. The scanning mirror 32 is supported by the housing unit 11 in a manner capable of driving in a rotatable around a center line of rotation along the Y-axis direction. The scanning mirror 32 swings within a driving range limited by a mechanical or electrical stopper.

The scanning motor 35 is, for example, a voice coil motor, a DC motor with brushes, a stepping motor, or the like. An output shaft of the scanning motor 35 is coupled to the scanning mirror 32 directly or indirectly via a drive mechanism such as a speed reducer. The scanning motor 35 is held by the housing unit 11 in a manner capable of driving the scanning mirror 32 in a rotatable together with the output shaft. The scanning motor 35 drives the scanning mirror 32 to rotate, i.e., to swing, within the driving range that is limited, according to a control signal from the control unit 51.

The scanning mirror 32 reflects the projected light beam Bp incident from the light projector unit 21 by the reflective surface 33 and irradiates the projected light beam Bp through the cover panel 12 onto the detection area Ad, thereby scanning the detection area Ad according to the rotation angle of the scanning motor 35. The scanning by the projected light beam Bp to the detection area Ad is substantially limited to scanning in the horizontal direction in the present embodiment, according to the rotational drive of the scanning mirror 32.

The scanning mirror 32 reflects the reflected beam Br incident from the target object in the detection area Ad through the cover panel 12 toward the light receiver unit 41 by the reflective surface 33 in accordance with the rotation angle of the scanning motor 35. Velocities of the projected light beam Bp and the reflected beam Br are sufficiently higher relative to a rotational speed of the scanning mirror 32. The reflected beam Br is then guided to the light receiver unit 41 in a reverse direction from the projected light beam Bp by receiving a reflection function of the scanning mirror 32, whose angle to the projected light beam Bp can be mimicked to be substantially the same rotation angle.

The light receiver unit 41 has a light receiver lens unit 42 and a light receiver detection unit 45. The light receiver lens unit 42 is constructed in a structure in which at least one light receiver lens 43 is held by a lens barrel 44. At least one light receiver lens 43 is mainly made of a light transmitting base material such as resin or glass, and is formed into a lens shape according to an optical function to be demonstrated. The light receiver lens 43 demonstrates an optical function so that the reflected beam Br from the scanning mirror 32 is formed into an image to the light receiver detection unit 45. The light receiver lens 43 is positioned in the lens barrel 44 with a light shielding property, formed, for example, of metal or resin. The light receiver lens unit 42 in such a configuration is aligned with the light receiver detection unit 45 to form a light receiver optical axis Or that guides the reflected beam Br from the scanning unit 31 to the light receiver detection unit 45 side, which is shifted in the Y-axis direction from the light projector optical axis Op of the light projector lens unit 26.

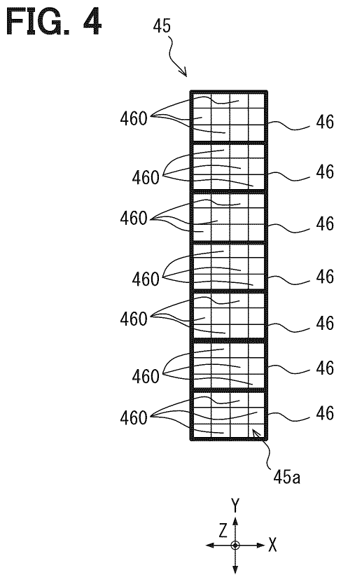

As shown in FIG. 4, the light receiver detection unit 45 is constructed by arranging a plurality of light receiver pixels 46 on a substrate 450 in an arrayed manner. The light receiver pixels 46 are arranged along at least the Y-axis direction. The light receiver detection unit 45 has a light receiver surface 45a on one side of the substrate, which has a rectangular contour that is long along the Y-axis direction and short along the X-axis direction. The light receiver surface 45a is configured as a collection of incident surfaces of each one of the light receiver pixels 46. Each one of the light receiver pixels 46 is further formed from a plurality of light receiver elements 460 respectively, for example, formed from single photon avalanche diodes (Single Photon Avalanche Diode). Each one of the light receiver pixels 46 receives the reflected beam Br incident from the light receiver lens unit 42 to the light receiver surface 45a, as shown in FIG. 1.

The light receiver detection unit 45 has an output circuit 47. The output circuit 47 performs sampling processing at each control cycle according to the control signal from the control unit 51 in a detection frame Fd (see FIG. 3) for each scanning line according to a rotation angle of the scanning mirror 32, which is synchronized with the projector light cycle of the projected light beam Bp by the projector light source unit 22. The output circuit 47 generates a detection signal by synthesizing the response output from the light receiver elements 460 of each one of the light receiver pixels 46 at each control cycle. The detection signal thus generated is output from the output circuit 47 to the control unit 51 by each scanning line.

The control unit 51 controls detection of objects in the detection area Ad in the external environment. The control unit 51 mainly includes at least one of a computer including a processor and a memory. The control unit 51 is connected to the projector light source unit 22, the scanning motor 35, and the light receiver detection unit 45. The control unit 51 controls the projector light source unit 22 to generate the projected light beam Bp in each projector light cycle. The control unit 51 also controls the scanning motor 35 to control scanning and reflection by the scanning mirror 32 synchronized with the projector light cycle by the projector light source unit 22. Furthermore, the control unit 51 generates detection data of target objects in the detection area Ad by processing the detection signals output from the light receiver detection unit 45 in the detection frame Fd according to the projector light cycle, the scanning by the scanning mirror 32, and reflection by the projector light source unit 22.

### Circuit Configuration Of Projector Light Source Unit

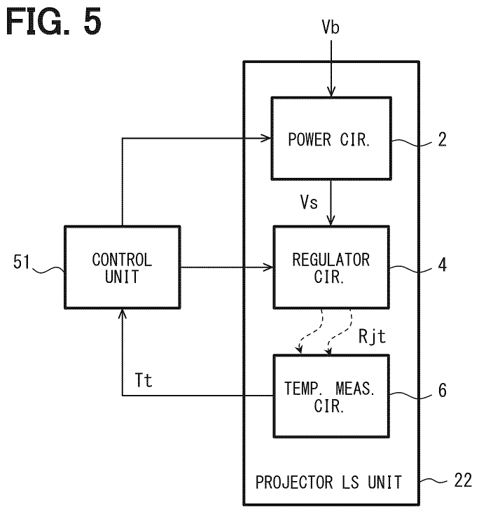

Next, a circuit configuration of the projector light source unit 22 is described. As shown in FIG. 5, the projector light source unit 22 has a power circuit 2, a regulator circuit 4, and a temperature measurement circuit 6. At least the regulator circuit 4 and the temperature measurement circuit 6 among those circuits 2, 4, and 6 are mounted on the same board.

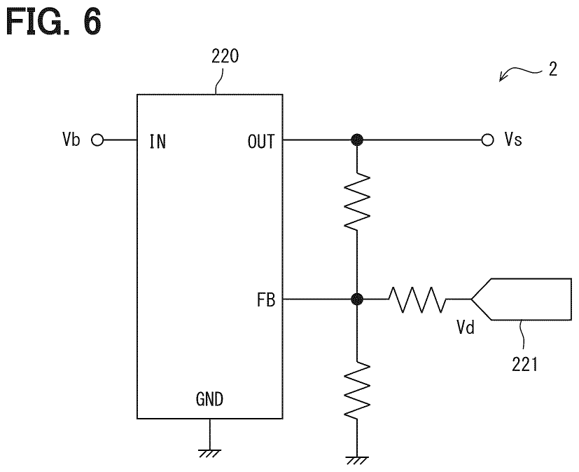

The power circuit 2 generates a power supply voltage Vs to be supplied to the regulator circuit 4 by boosting an input voltage Vb supplied from a battery of the vehicle. For this purpose, in the power circuit 2 as shown in FIG. 6, the output terminal of the DC-DC regulator 220 is connected to the feedback terminal of the DC-DC regulator 220 and the output node of the digital analog converter 221 of the regulator 220. As a result, the digital-analog converter 221 controls the set voltage Vd of the output from the output node according to the control signal from the control unit 51, and the DC-DC regulator 220 adjusts the power supply voltage Vs of the output from the output terminal based on the input voltage Vb.

Such the power circuit 2 may also supply the temperature measurement circuit 6 with a power supply voltage Vs. The power circuit 2 may be shared by the projector light source unit 22 and the light receiver detection unit 45 to supply the power supply voltage Vs to the light receiver detection unit 45 as well.

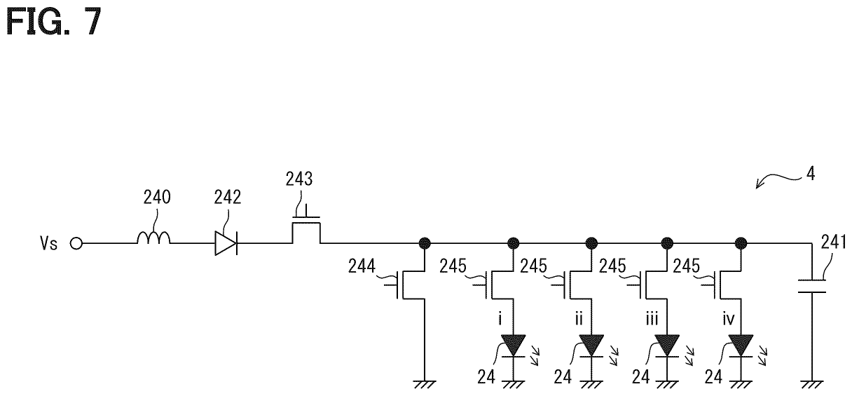

The regulator circuit 4 shown in FIG. 5 controls the luminous output PI of each one of the light source elements 24 by regulating the applied voltage VI to each one of the light source elements 24 as shown in FIG. 9 from the power supply voltage Vs supplied by the power circuit 2. For this purpose, as shown in FIG. 7, in the regulator circuit 4, an inductor 240 and a capacitor 241 are connected in series in this order in the path from the power circuit 2 to the ground terminal at ground potential. That is, the regulator circuit 4 is an LC series-connected resonant circuit. In such a regulator circuit 4, the inductor 240 is mainly composed of an induction coil. In the regulator circuit 4, the capacitor 241 is mainly composed of a heat-resistant capacitor, such as an electrolytic type, for example.

In the regulator circuit 4, the rectifier element 242 and the first switching element 243 are connected in series in this order in the path from the inductor 240 to the capacitor 241. Further, the regulator circuit 4 is provided with a second switching element 244 in one of the three or more branch paths that branch off from the path between the first switching element 243 and the capacitor 241 and are connected to the ground terminal. In such the regulator circuit 4, the rectifier element 242 is mainly composed of a rectifier diode that provides current rectification function from the inductor 240 side to the capacitor 241 side. The first and second switching elements 243 and 244 in the regulator circuit 4 are mainly composed of field effect transistors such as MOSFETs (Metal Oxide Semiconductor Field Effect Transistors) that turn on and off according to individual control signals from the control unit 51, respectively.

In the regulator circuit 4, a pair of the third switching element 245 and the light source element 24 are provided in the branch paths that branch off from the path between the first switching element 243 and the capacitor 241 and are connected to the ground terminal, which is different from the second switching element 244, respectively. In such regulator circuit 4, the third switching elements 245 of each one of the pair is composed mainly of field-effect transistors, such as MOSFETs, which are turned on and off according to individual control signals from the control unit 51. In FIG. 7, a Greek numeral attached to each branch path where a pair of the third switching element 245 and the light source element 24 is provided represents a light emission sequence i to iv of the light source elements 24 shown in FIGS. 2 and 3, respectively, as described above.

In the regulator circuit 4, ON states at a fixed time duration in the second switching element 244 are repeated according to the light emission sequence i to iv of the light source elements 24 in the detection frame Fd in each scanning line shown in FIG. 3. Further, in the regulator circuit 4, ON states at variable time durations according to the individual control signals from the control unit 51 are repeated in the first switching element 243 according to the light emission sequence i to iv of the light source elements 24. The timing at which the first switching element 243 begins to turn on is adjusted to synchronize with the timing at which the second switching element 244 begins to turn on. As a result, in the regulator circuit 4, the charge voltages Vc charged to the capacitor 241 by the coil current Ic are regulated individually for each one of the light emission sequence i to iv of the light source elements 24.

In the detection frame Fd, the regulator circuit 4 further perform a switching to an ON state at the pulse luminescence time duration of the third switching element 245 of the same pair of the light source element 24 in the corresponding one of the light emission sequence after a certain time from the timing when a completion of an ON of the second switching element 244 (i.e., the timing of an OFF) for each one of the light emission sequence i to iv for the light source elements 24. At this time, for each one of the light source elements 24, the timing at which the third switching element 245 begins to turn on is adjusted so that it is later than the timing at which the first switching element 243 completes the ON (i.e., the timing of the OFF) in corresponding one of the light emission sequence. In the regulator circuit 4, the charge voltage Vc, which is regulated individually for each one of the light emission sequence i to iv for the light source elements 24 as shown in FIG. 3, is applied as the applied voltage VI to the light source elements 24 in the corresponding one of the light emission sequence.

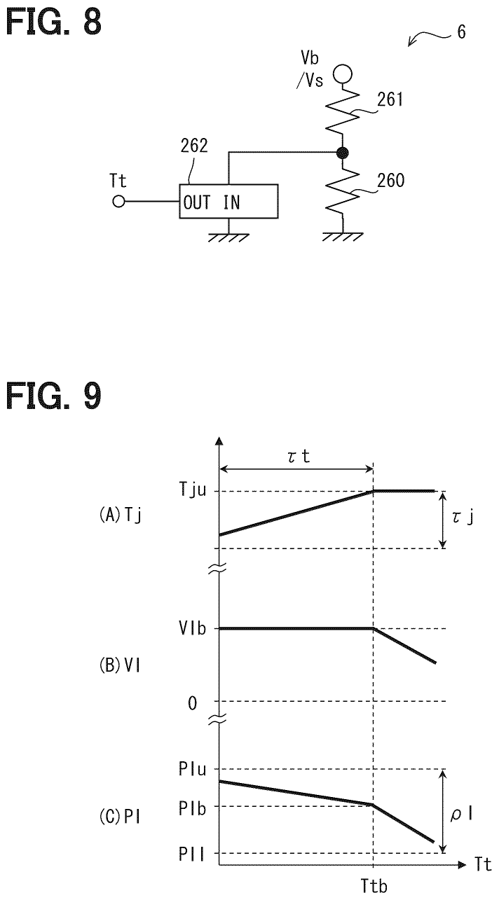

The temperature measurement circuit 6 shown in FIG. 5 measures a heat transfer temperature Tt, i.e., the unit of temperatures in the following description is Celsius degrees, transferred from each one of the light source elements 24 to a common surroundings point and outputs it to the control unit 51. For this purpose, in the temperature measurement circuit 6 as shown in FIG. 8, a thermistor element 260 and a series resistor 261 are connected in series in a reverse order of this description in a path from a battery of an input voltage Vb or the power circuit 2 of a power supply voltage Vs to a ground terminal. In addition, at least the thermistor element 260 is disposed in a place of a surroundings area common to the light source elements 24 in the regulator circuit 4, as shown in FIG. 2 in the temperature measuring circuit 6.

The thermistor element 260 in the temperature measurement circuit 6 is mainly composed of a thermistor resistor with a large resistance temperature coefficient so that a resistance value changes in accordance with an amount of heat transferred from the junctions of the light source elements 24 through a circuit board where the circuits 4 and 6 are mounted. The series resistor 261 in the temperature measurement circuit 6 is mainly composed of a high-precision resistor with a small resistance temperature coefficient to output a resistance value of the thermistor element 260, which is correlated with a voltage between two ends. Therefore, a conversion circuit 262 is further connected in the temperature measurement circuit 6 so that the resistance value of the thermistor element 260 correlated to the voltage between the two ends of the series resistor 261 is converted to the heat transfer temperature Tt from the light source elements 24 to the thermistor element 260 and outputs a digital signal.

### Control Principle Of Control Unit

Next, the control principle of the projector light source unit 22 by the control unit 51 is explained. The control principle by the control unit 51 is constructed to perform monitoring the heat transfer temperature Tt which is output from the temperature measurement circuit 6 as shown in FIGS. 5 and 9, and based on a monitoring results, controlling the luminous output PI in accordance with the applied voltage VI for each of the light emission sequences i to iv of the light source element 24 as shown in FIGS. 3 and 9.

Specifically, as shown in FIG. 9, the allowable temperature range Tj below an upper temperature Tju is commonly defined for the light source elements 24 as the temperature range allowed for the junction temperature Tj of the light source elements 24. The upper temperature Tju of the allowable temperature range Tj is set below the rated temperature common to the light source elements 24. Furthermore, a reference heat transfer range It is commonly defined for the light source elements 24 as a temperature range of the heat transfer temperature Tt corresponding to an allowable temperature range Tj. A boundary temperature Ttb, which separates an inside and an outside at the high temperature side of the reference heat transfer range Tt, is commonly set for the light source elements 24 as the heat transfer temperature Tt corresponding to the upper temperature Tju of the allowable temperature range Tj according to the correlation in the mathematical formula 1.

In the mathematical formula 1, ηb is set commonly for the light source elements 24 as the luminous efficiency at the boundary temperature Ttb among the heat transfer temperatures Tt. In the mathematical formula 1, Rjt is set to an individual value according to relative positions of each one of the light source element 24 to the thermistor element 260 (see FIG. 2) as the thermal resistance in the heat transfer path from the junction of the light source element 24 through the mounting board of the circuits 4 and 6 (see FIG. 5). In the mathematical formula 1, Plb is set to an individual value for each one of the light source elements 24 as the luminous output PI at the boundary temperature Ttb of the heat transfer temperature Tt.

As shown in FIG. 9, the luminous output Plb at the boundary temperature Ttb is set to an intermediate value within an allowed output range pl, where the allowed output range pl is commonly allowed for the luminous output PI of the light source elements 24. In the allowable output range pl, an upper maximum output Plu to ensure a safety of the projected light beam Bp to the human eye in the outside world, and a lower minimum output PII to ensure an accuracy of the detection signal by ensuring the intensity of the reflected beam Br are defined. As described above, the applied voltage VI to control the luminous output PI to the luminous output Plb within the allowable output range pl is set as the applied voltage Vlb individually for each one of the light source elements 24 according to the correlation in the mathematical formula 2 with the capacitance C of the capacitor 241 as a constant.

Therefore, if the heat transfer temperature Tt commonly monitored for the light source elements 24 falls within the reference heat transfer range It as shown in FIG. 9, the control unit 51 maintains the applied voltage VI for each one of the light source elements 24 at the applied voltage Vlb which is individual at the boundary temperature Ttb. However, at the heat transfer temperature Tt below the boundary temperature Ttb within the reference heat transfer range Tt, the junction temperature Tj of each one of the light source elements 24 is maintained within the allowable temperature range Tj by maintaining the applied voltage Vlb under the correlation of the mathematical formulas 3 and 4. At the heat transfer temperature Tt below the boundary temperature Ttb within the reference heat transfer range Tt, the luminous output PI of each one of the light source elements 24 is individually controlled within the allowable output range pl by maintaining the applied voltage Vlb under the correlation of the mathematical formulas 3 and 4. Here, in the mathematical formulas 3 and 4, n is specified by an arithmetic formula, table, or map common to each one of the light source elements 24 as a function of the luminous efficiency, which decreases as the heat transfer temperature Tt increases.

On the other hand, if the heat transfer temperature Tt commonly monitored for the light source elements 24 rises outside the reference heat transfer range It as shown in FIG. 9, the control unit 51 regulates the applied voltage VI for the light source elements 24 individually to absorb the temperature change amount ΔTj from the upper temperature Tju of the junction temperature Tj under the correlation of the mathematical formulas 5 and 6. The luminous output PI is individually controlled for each one of the light source elements 24 so that such a temperature change amount ΔTj is absorbed under the correlation of the mathematical formulas 5 and 6.

In the mathematical formulas 5 and 6, ΔTt is defined as a heat transfer change amount, as a change in the heat transfer temperature Tt from the boundary temperature Ttb. In the mathematical formulas 5 and 6, Δη is specified by an arithmetic formula, table, or map common to the light source elements 24 as a function of the efficiency change amount of the luminous efficiency n changed according to the heat transfer change amount ΔTt from the luminous efficiency ηb at the boundary temperature Ttb. In order to absorb the temperature change amount ΔTj that correlates to the heat transfer change amount ΔTt and the efficiency change amount Δη according to the mathematical formulas 5 and 6, each of the 24 light source elements carries out individual control of the luminous output PI by individual regulating of the applied voltage VI so that the temperature change amount ΔTj becomes practically zero (0).

At the heat transfer temperature Tt outside the reference heat transfer range Tt, since an occurrence of the temperature change amount ΔTj is suppressed for the light source elements 24 according to the correlation of the mathematical formulas 5 and 6, the junction temperature Tj of the light source elements 24 are maintained at the upper temperature Tju of the allowable temperature range Tj, as shown in FIG. 9. In addition, at the heat transfer temperature Tt outside the reference heat transfer range Tt according to the correlation of the mathematical formulas 5 and 6, the luminous output PI of each one of the light source elements 24 are individually controlled to decrease within the allowable output range pl with respect to a decrease in the applied voltage VI in response to an increase in the heat transfer temperature Tt.

### Functions and Advantages

Functions and advantages of the first embodiment explained so far are described below.

In the light projector unit 21 of the first embodiment, the heat transfer temperature Tt transferred to the surroundings of the light source element 24 is monitored by the control unit 51. Therefore, the control unit 51 further focuses on the temperature change amount ΔTj of the junction temperature Tj at the light source element 24, which is correlated with the heat transfer change amount ΔTt of the heat transfer temperature Tt and the efficiency change amount Δη of the luminous efficiency n, which decreases as the heat transfer temperature Tt increases. Then, in the control unit 51, the luminous output PI at the light source element 24 is controlled to absorb the temperature change amount ΔTj in the junction temperature Tj, as a result, it is possible to suppress a decrease in the life of the light source element 24 caused by temperature rise and to ensure durability.

In the control unit 51 of the first embodiment, the applied voltage VI to the light source element 24 is precisely regulated to absorb the temperature change amount ΔTj of the junction temperature Tj, so that control to properly establish such absorption can be realized for the luminous output PI. Therefore, it is possible to increase the reliability of ensuring durability.

According to the first embodiment, the temperature range set for the heat transfer temperature Tt corresponding to the allowable temperature range Tj allowed for the junction temperature Tj is focused as the reference heat transfer range Tt. Therefore, in the control unit 51, if the heat transfer temperature Tt rises outside the reference heat transfer range Tt, the luminous output PI is controlled to absorb the temperature change amount ΔTj of the junction temperature Tj. According to this, it is possible to absorb the temperature change amount ΔTj of the junction temperature Tj by appropriately targeting a rising situation of the heat transfer temperature Tt outside the reference heat transfer range It, where the junction temperature Tj is expected to rise outside the allowable temperature range Tj. Therefore, it is possible to increase the reliability of ensuring durability.

According to the first embodiment, the output range allowed for the luminous output PI is focused on as the allowable output range pl. Therefore, in the control unit 51, if the heat transfer temperature Tt rises outside the reference heat transfer range Tt, the luminous output PI is controlled within the allowable output range pl to absorb the temperature change amount ΔTj of the junction temperature Tj. According to this, it is possible not only to increase the reliability of ensuring durability, but also to ensure the safety of the projected light beam Bp and the accuracy of the detection signal by ensuring the intensity of the reflected beam Br, by the luminous output PI within the allowable output range pl.

In the control unit 51 of the first embodiment, if the heat transfer temperature Tt is within the reference heat transfer range Tt, the luminous output PI is controlled within the allowable output range pl by maintaining the applied voltage VI to the light source element 24. According to this, under the heat transfer temperature Tt within the reference heat transfer range Tt, where the junction temperature Tj within the allowable temperature range Tj is assumed, it is possible to increase the luminous output PI as much as possible within the allowable output range pl to ensure the safety of the projected light beam Bp and reduce a control load to ensure the accuracy of the detection signal by the voltage holding function.

In the projection unit 21 of the first embodiment, since the projector light source unit 22 with a plurality of light source elements 24 generates a projection beam Bp, the control unit 51 monitors the heat transfer temperature Tt from each light source element 24 to a common surroundings point. Therefore, the control unit 51 further controls the luminous output PI at each one of the light source elements 24 individually to absorb the temperature change amount ΔTj of the junction temperature Tj for each one of the light source elements 24. Therefore, it is possible to suppress the decrease in a service life caused by the temperature rise in each one of the light source elements 24 and to ensure the durability of each one of the light source elements 24.

### Second Embodiment

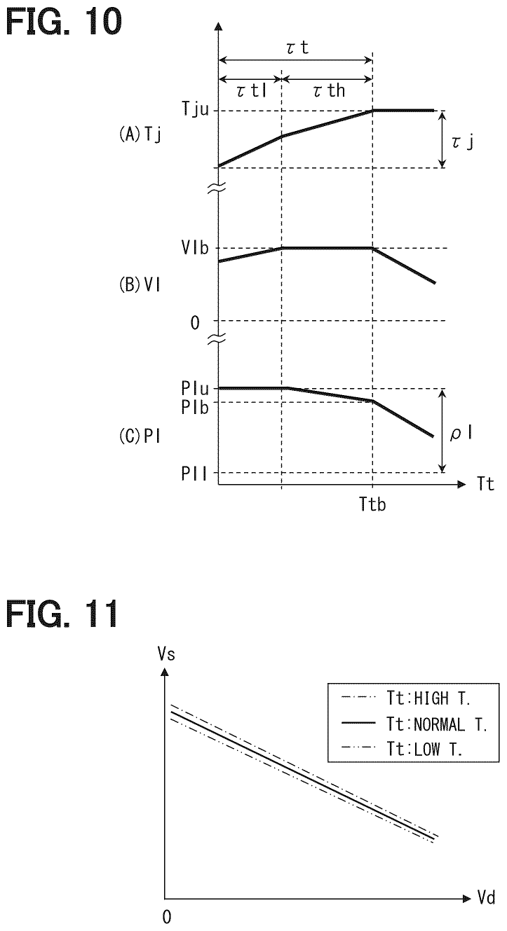

A second embodiment is a modification to the first embodiment. As shown in FIG. 10, the reference heat transfer range It of the second embodiment is divided into a high temperature range Tth where the heat transfer temperature Tt is on a side of the boundary temperature Ttb and a low temperature range Ttl where the heat transfer temperature Tt is lower than the high temperature range Tth.

Therefore, if the heat transfer temperature Tt is within the high temperature range Tth, the control unit 51 of the second embodiment maintains the applied voltage VI for each one of the light source elements 24 at the applied voltage Vlb individually so that the luminous output PI of each one of the light source elements 24 is individually controlled within the allowable output range pl, as was done for the reference heat transfer range Tt in the first embodiment. On the other hand, if the heat transfer temperature Tt is in the low temperature range Ttl, the control unit 51 of the second embodiment regulates the applied voltage VI for each one of the light source elements 24 individually so that the luminous output PI of each one of the light source elements 24 is commonly controlled to the maximum output Plu in the allowable output range pl under the correlation of the mathematical formulas 7 and 8. As a result, in both the high temperature range Tth and the low temperature range Ttl, the junction temperature Tj of the light source elements 24 are kept within the allowable temperature range Tj, and the luminous output PI of the light source elements 24 are controlled to be variable or maintained within the allowable output range pl.

Thus, in the control unit 51 of the second embodiment, if the heat transfer temperature Tt within the reference heat transfer range It is within the low temperature range Ttl, which is lower than the high temperature range Tth that holds the applied voltage VI to the light source element 24, the luminous output PI is controlled to the maximum output Plu within the allowable output range pl. According to this, in the high temperature range Tth within the reference heat transfer range Tt, it is possible to increase the luminous output PI as much as possible within the allowable output range pl where the safety of the projected light beam Bp is ensured, and to reduce the control load to ensure the accuracy of the detection signal by the voltage holding function. On the other hand, in the low temperature range Ttl within the reference heat transfer range Tt, it is possible to increase the luminous output PI to the maximum output Plu within the allowable output range pl where the safety of the projected light beam Bp is ensured, and to improve the accuracy of the detection signal.

### Third Embodiment

A third embodiment is a modification to the first embodiment. The third embodiment focuses on a temperature dependent characteristic in which the power supply voltage Vs output from the DC-DC regulator 220 varies with respect to a set voltage Vd output from the digital analog converter 221 in the power circuit 2 (see FIG. 6 in the first embodiment) in accordance with a rise and fall of the heat transfer temperature Tt as shown in FIG. 11. Therefore, the control unit 51 of the third embodiment controls the set voltage Vd of the output from the digital analog converter 221 to absorb fluctuations in the power supply voltage Vs according to rises and falls of the heat transfer temperature Tt.

In the projection unit 21 of the third embodiment, as in the first embodiment, the applied voltage VI applied to the light source element 24 is regulated by the regulator circuit 4 from the power supply voltage Vs supplied by the power circuit 2. Therefore, the control unit 51 of the third embodiment controls the power circuit 2 to absorb fluctuations in the power supply voltage Vs according to rises and falls of the heat transfer temperature Tt. According to this, the applied voltage VI applied to the light source element 24 can be accurately adjusted from the power supply voltage Vs, which is stable, to absorb the temperature change amount ΔTj of the junction temperature Tj. Therefore, the control to properly absorb the temperature change amount ΔTj can be realized for the luminous output PI, and the reliability of ensuring durability can be improved.

### Other Embodiments

Although a plurality of embodiments have been described above, the present disclosure is not to be construed as being limited to these embodiments, and can be applied to various embodiments and combinations within a scope not deviating from the gist of the present disclosure.

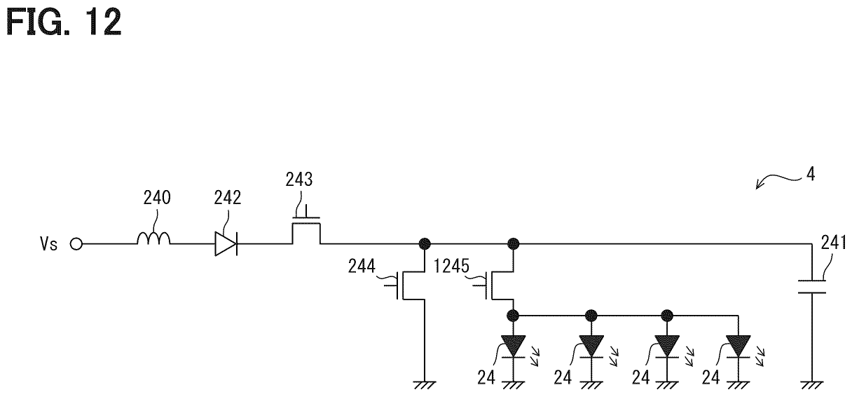

In variations of the first to third embodiments, a third switching element 1245 common for the light source elements 24 is connected to as shown in FIG. 12, the light source elements 24 may emit light simultaneously by turning on the third switching element 1245 to form a line-shaped projected light beam Bp jointly. In this case, the luminous output PI should be controlled commonly for the light source elements 24 by regulating the applied voltage VI commonly for the light source elements 24.

In variations of the first to third embodiments, only one pair of the light source element 24 and the third switching element 245 may be provided. In variations of the first to third embodiments, at least the regulator circuit 4 of the circuits 2, 4, and 6 may be provided individually for each one of the light source elements 24 as a circuit configuration having only one pair of the light source element 24 and the third switching element 245. In a variations of the second embodiment, the third embodiment may be applied.

In variations of the first to third embodiments, a Y-axis direction along the horizontal direction and an X-axis direction along the vertical direction may be defined. In modified examples of the first to third embodiments, a moving object to which the optical sensor 10 is applied may be, e.g., a traveling robot whose traveling can be remotely controlled. In variations of the first to third embodiments, the optical sensor 10 may be applied to objects other than moving objects, such as stationary structures.

### Notes

The present specification discloses a plurality of technical ideas listed below and a plurality of combinations thereof.

### Technical Idea 1

An optical sensor (10) that projects a projected light beam (Bp) and receives a reflected beam (Br) that is reflected with respect to the projected light beam, the optical sensor comprising:
a light projector unit (21) that generates the projected light beam by a light source element (24);
a light receiver unit (41) that outputs a detection signal by receiving the reflected beam; and
a control unit (51) that controls the light projector unit and the light receiver unit, wherein the control unit is configured to perform:
monitoring a heat transfer temperature (Tt) transferred to a surroundings of the light source element in the light projector unit; and
controlling a luminous output (PI) at the light source element to absorb a temperature change amount in a junction temperature (Tj) at the light source element, which is correlated with an efficiency change amount in a luminous efficiency that decreases as the heat transfer temperature increases at the light source element and a heat transfer change amount in the heat transfer temperature.

### Technical Idea 2

The optical sensor according to Technical Idea 1, wherein the control unit is configured to perform:
controlling the luminous output by regulating an applied voltage (VI) to the light source element to absorb the temperature change amount.

### Technical Idea 3

The optical sensor according to Technical Ideas 1 or 2, wherein
the control unit is configured to perform:
controlling the luminous output to absorb the temperature change amount if the heat transfer temperature rises outside a reference heat transfer range (Tt), the reference heat transfer range being a temperature range set for the heat transfer temperature corresponding to an allowable temperature range (Tj) allowed for the junction temperature.

### Technical Idea 4

The optical sensor according to Technical Idea 3, wherein
the control unit is configured to perform:
controlling the luminous output within an allowable output range to absorb the temperature change amount if the heat transfer temperature rises outside the reference heat transfer range, the allowable output range being an output range allowed for the luminous output.

### Technical Idea 5

The optical sensor according to Technical Idea 4, wherein
the control unit is configured to perform:
controlling the luminous output within the allowable output range by maintaining an applied voltage (VI) to the light source element if the heat transfer temperature is within the reference heat transfer range.

### Technical Idea 6

The optical sensor according to Technical Idea 5, wherein the control unit is configured to perform:
maintaining a maximum output (Plu) of the luminous output within the allowable output range if the heat transfer temperature within the reference heat transfer range is within a low temperature range (Ttl), which is lower than a high temperature range (Tth) that maintains the applied voltage (VI) to the light source element.

### Technical Idea 7

The optical sensor according to any one of Technical Ideas 1-6, wherein
the light projector unit includes:
a projector light source unit (22) with a plurality of light source elements that generate the projected light beam, and wherein
the control unit is configured to perform:
monitoring the heat transfer temperature from each one of the light source element to a common surroundings point; and
individually controlling the luminous output at each one of the light source elements to absorb the temperature change amount for each one of the light source elements.

### Technical Idea 8

The optical sensor according to any one of Technical Ideas 2, 5, and 6, wherein
the light projector unit further includes:
a power circuit (2) that supplies a power supply voltage (Vs); and
a regulator circuit (4) for regulating an applied voltage (VI) from the power supply voltage to the light source element, and wherein
the control unit is configured to perform:
controlling the power circuit to absorb fluctuations in the power supply voltage according to rises and falls in the heat transfer temperature.

$$Tju = Ttb + Rjt \cdot Plb \cdot ( \frac{1}{η b} - 1 ) \qquad [ Math 1 ]$$

$$Plb = \frac{1}{2} \cdot C \cdot {Vlb}^{2} \cdot η b \qquad [ Math 2 ]$$

$$Tj = Tt + Rjt \cdot Pl \cdot ( \frac{1}{η} - 1 ) \qquad [ Math 3 ]$$

$$Pl = \frac{1}{2} \cdot C \cdot {Vlb}^{2} \cdot η \qquad [ Math 4 ]$$

$$Tj + Δ Tj = Tt + Δ Tt + Rjt \cdot Pl \cdot ( \frac{1}{η b + Δ η} - 1 ) \qquad [ Math 5 ]$$

$$Pl = \frac{1}{2} \cdot C \cdot {Vl}^{2} \cdot ( η b + Δη ) \qquad [ Math 6 ]$$

$$Tj = Tt + Rjt \cdot Plu \cdot ( \frac{1}{η} - 1 ) \qquad [ Math 7 ]$$

$$Plu = \frac{1}{2} \cdot C \cdot {Vl}^{2} \cdot η \qquad [ Math 8 ]$$

What is claimed is:

1. An optical sensor that projects a projected light beam and receives a reflected beam that is reflected with respect to the projected light beam, the optical sensor comprising:
a light projector unit that generates the projected light beam by a light source element;
a light receiver unit that outputs a detection signal by receiving the reflected beam; and
a control unit that controls the light projector unit and the light receiver unit, wherein
the control unit, including at least one processor circuit, is configured to perform:
monitoring a heat transfer temperature transferred to a surroundings of the light source element in the light projector unit; and
controlling a luminous output at the light source element to absorb a temperature change amount in a junction temperature at the light source element, which is correlated with an efficiency change amount in a luminous efficiency that decreases as the heat transfer temperature increases at the light source element and a heat transfer change amount in the heat transfer temperature.

2. The optical sensor according to claim 1, wherein
the control unit is configured to perform:
controlling the luminous output by regulating an applied voltage to the light source element to absorb the temperature change amount.

3. The optical sensor according to claim 1, wherein
the control unit is configured to perform:
controlling the luminous output to absorb the temperature change amount if the heat transfer temperature rises outside a reference heat transfer range (Tt), the reference heat transfer range being a temperature range set for the heat transfer temperature corresponding to an allowable temperature range (Tj) allowed for the junction temperature.

4. The optical sensor according to claim 3, wherein
the control unit is configured to perform:
controlling the luminous output within an allowable output range to absorb the temperature change amount if the heat transfer temperature rises outside the reference heat transfer range, the allowable output range being an output range allowed for the luminous output.

5. The optical sensor according to claim 4, wherein
the control unit is configured to perform:
controlling the luminous output within the allowable output range by maintaining an applied voltage to the light source element if the heat transfer temperature is within the reference heat transfer range.

6. The optical sensor according to claim 5, wherein
the control unit is configured to perform:
maintaining a maximum output of the luminous output within the allowable output range if the heat transfer temperature within the reference heat transfer range is within a low temperature range (Ttl), which is lower than a high temperature range (Tth) that maintains the applied voltage to the light source element.

7. The optical sensor according to claim 1, wherein
the light projector unit includes:
a projector light source unit with a plurality of light source elements that generate the projected light beam, and wherein
the control unit is configured to perform:
monitoring the heat transfer temperature from each one of the light source element to a common surroundings point; and
individually controlling the luminous output at each one of the light source elements to absorb the temperature change amount for each one of the light source elements.

8. The optical sensor according to claim 2, wherein
the light projector unit further includes:
a power circuit that supplies a power supply voltage; and
a regulator circuit for regulating an applied voltage from the power supply voltage to the light source element, and wherein
the control unit is configured to perform:
controlling the power circuit to absorb fluctuations in the power supply voltage according to rises and falls in the heat transfer temperature.

9. The optical sensor according to claim 5, wherein
the light projector unit further includes:
a power circuit that supplies a power supply voltage; and
a regulator circuit for regulating an applied voltage from the power supply voltage to the light source element, and wherein
the control unit is configured to perform:
controlling the power circuit to absorb fluctuations in the power supply voltage according to rises and falls in the heat transfer temperature.

10. The optical sensor according to claim 6, wherein
the light projector unit further includes:
a power circuit that supplies a power supply voltage; and
a regulator circuit for regulating an applied voltage from the power supply voltage to the light source element, and wherein
the control unit is configured to perform:
controlling the power circuit to absorb fluctuations in the power supply voltage according to rises and falls in the heat transfer temperature.
